(19) United States
(12) Patent Application Publication
(10) Pub. No.: US 2026/0190361 A1
(43) Pub. Date: Jul. 2, 2026

(54) SEMICONDUCTOR DEVICE INCLUDING CAPACITOR

(71) Applicant: SK hynix Inc., Gyeonggi-do (KR)

(72) Inventors: Sang Won CHO, Gyeonggi-do (KR); Woo Young PARK, Gyeonggi-do (KR); Han Seung LEE, Gyeonggi-do (KR); Hyun Jin CHO, Gyeonggi-do (KR); Seung Taeg OH, Gyeonggi-do (KR); Dong Hyun LEE, Gyeonggi-do (KR)

(21) Appl. No.: 19/238,536

(22) Filed: Jun. 16, 2025

(30) Foreign Application Priority Data
Dec. 31, 2024 (KR) 10-2024-0201632

(51) Int. Cl. H10D 1/68; H10B 12/00

(52) U.S. Cl. CPC H10D 1/696; H10B 12/315; H10B 12/318; H10D 1/716; H10B 12/033

(57) ABSTRACT

A semiconductor device may include a conductive pattern on a substrate. A first electrode may be disposed on the conductive pattern. A support for supporting the first electrode may be provided. An auxiliary layer disposed on a side surface of the first electrode and extending between the first electrode and the support may be provided. The auxiliary layer may include NbTiO, NbTiN, NbTiON, NbTaO, NbTaN, NbTaON, MoTiO, MoTiN, MoTiON, MoTaO, MoTaN, MoTaON, InTiO, InTiN, InTiON, InTaO, InTaN, InTaON, or a combination thereof. A capacitor dielectric layer may be disposed on the auxiliary layer. A second electrode may be disposed on the capacitor dielectric layer.

### CROSS-REFERENCES TO RELATED APPLICATION

The present application claims priority under 35 U.S.C. 119(a) to Korean patent application number 10-2024-0201632 filed on Dec. 31, 2024, which is incorporated herein by reference in its entirety.

### TECHNICAL FIELD

Embodiments of the present disclosure relate generally to semiconductor technology and more particularly to a semiconductor device having a capacitor and a method for forming the same.

### BACKGROUND

Semiconductor memories, such as dynamic random-access memory (DRAM), include a plurality of capacitors. As semiconductor devices become more highly integrated, various technologies are being explored to reduce the size of capacitors and enhance their capacity. A reduction in the gap between the electrodes of a capacitor results in increased leakage current. Furthermore, the shrinkage of the electrodes leads to greater variability or dispersion of the capacitance.

### SUMMARY

Embodiments of the present disclosure provide a semiconductor device having a capacitor and a method for forming the same.

The advantages of the embodiments of the present disclosure are not limited to those set forth herein, and other unmentioned advantages would be apparent to those with ordinary skill in the relevant art from the following description.

A semiconductor device according to an embodiment of the present disclosure may comprise a conductive pattern on a substrate. A first electrode may be disposed on the conductive pattern. A support for supporting the first electrode may be provided. An auxiliary layer disposed on a side surface of the first electrode and extending between the first electrode and the support may be provided. A capacitor dielectric layer may be disposed on the auxiliary layer. A second electrode may be disposed on the capacitor dielectric layer.

A semiconductor device according to another embodiment of the present disclosure may comprise a conductive pattern on a substrate. A first electrode may be disposed on the conductive pattern. A support for supporting the first electrode may be provided. An auxiliary layer may be disposed on a side surface of the first electrode. A lower area of the auxiliary layer close to the conductive pattern may have a larger thickness than an upper area of the auxiliary layer relatively far from the conductive pattern. A capacitor dielectric layer may be disposed on the auxiliary layer. A second electrode may be disposed on the capacitor dielectric layer.

A semiconductor device according to yet another embodiment of the present disclosure may comprise a source area connected to a bit line. A drain area facing the source area may be provided. A channel area may be disposed between the source area and the drain area. A word line adjacent to the channel area may be provided. A gate dielectric layer may be disposed between the channel area and the word line. A conductive pattern connected to the drain area may be provided. A first electrode may be disposed on the conductive pattern. A support for supporting the first electrode may be provided. An auxiliary layer disposed on a side surface of the first electrode and extending between the first electrode and the support may be provided. A capacitor dielectric layer may be disposed on the auxiliary layer. A second electrode may be disposed on the capacitor dielectric layer.

According to embodiments of the present disclosure, there may be provided a semiconductor device having a capacitor and a method for forming the same.

The features, advantages, and effects of the embodiments of the present disclosure are not limited to the foregoing, and other features, advantages, and effects will become apparent to those with ordinary skill in the relevant art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIGS. 1 to 6 are cross-sectional views illustrating a semiconductor device according to embodiments of the present disclosure.

FIGS. 7 to 28 are cross-sectional views illustrating a method for forming a semiconductor device according to embodiments of the present disclosure.

### DETAILED DESCRIPTION

Hereinafter, embodiments of the present disclosure are described in detail with reference to the accompanying drawings. In assigning reference numerals to components of each drawing, the same components may be assigned the same numerals even when they are shown on different drawings. In instances where including detailed descriptions of known art or functions may obscure the clarity of the present disclosure, such details may be omitted, provided that the omission does not detract from the understanding of the claimed invention.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

As used herein, the singular forms “a”, “an” and “the” are intended to include the plural forms as well, unless the context clearly indicates otherwise.

Hereinafter, embodiments of the present disclosure are described in detail with reference to the accompanying drawings. In assigning reference numerals to components of each drawing, the same components may be assigned the same numerals even when they are shown on different drawings. As used herein, when a component “includes,” “has,” or “is composed of” another component, the component may add other components unless the term “only” is used with “includes, has, or is composed of” the other component.

Labels such as “first,” “second,” “A,” “B,” “(a),” and “(b),” may be used in describing the components of the embodiments of the present disclosure. These labels are provided merely to distinguish a component from another, and the essence, order, or number of the components are not limited by the labels.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

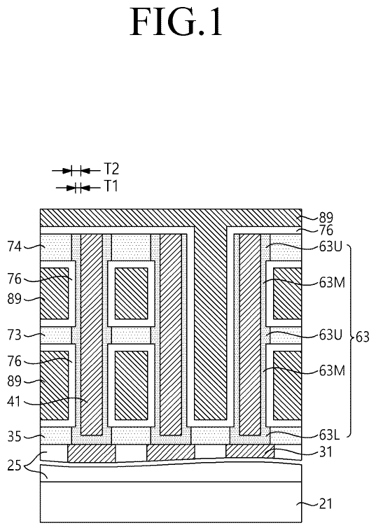

FIGS. 1 to 6 are cross-sectional views illustrating a semiconductor device according to embodiments of the present disclosure. In an embodiment, a semiconductor device may include a memory device such as a cell array of dynamic random access memory (DRAM).

Referring to FIG. 1, a semiconductor device according to embodiments of the present disclosure may include a substrate 21, an interlayer insulation layer 25 disposed on the substrate 21, a conductive pattern 31, an etch stop layer 35, a lower electrode 41, an auxiliary layer 63, supports 73 and 74, a capacitor dielectric layer 76, and an upper electrode 89. In an embodiment, the lower electrode 41 may correspond to a first electrode, and the upper electrode 89 may correspond to a second electrode. The auxiliary layer 63 may include a lower level auxiliary layer 63L, an intermediate level auxiliary layer 63M, and an upper level auxiliary layer 63U. The supports 73 and 74 may include an intermediate support 73 and an upper support 74.

The interlayer insulation layer 25 may cover the substrate 21. The conductive pattern 31 may be disposed in the interlayer insulation layer 25. A plurality of conductive patterns 31 may be disposed at regular intervals from each other in the interlayer insulating layer with the upper surfaces (i.e., the top surfaces) of the conductive pattern 31 and the interlayer insulation layer 25 forming the same or substantially the same plane. The upper surfaces (i.e., the top surfaces) of the conductive pattern 31 and of the interlayer insulation layer 25 may be coplanar.

The etch stop layer 35 may cover the conductive patterns 31 and the interlayer insulation layer 25. The lower electrode 41 and the auxiliary layer 63 penetrating the etch stop layer 35 may be disposed on the conductive pattern 31. The lower electrode 41 may be aligned on the conductive pattern 31. The height of the lower electrode 41 may be larger than the horizontal width. The lower electrode 41 may have an aspect ratio of 10:1 or more. In an embodiment, the auxiliary layer 63 may completely surround the side surface and lower surface of the lower electrode 41. The lower electrode 41 may have a pillar shape.

The auxiliary layer 63 may directly contact the side surface and the lower surface of the lower electrode 41. The lower electrode 41 may include Titanium (Ti), Tantalum (Ta), Titanium Nitride (TiN), Tantalum Nitride (TaN), Titanium Oxide (TiO), Tantalum Oxide (TaO), Titanium Oxynitride (TiON), Tantalum Oxynitride (TaON), or a combination thereof. The auxiliary layer 63 may include Niobium Titanium Oxide (NbTiO), Niobium Titanium Nitride (NbTiN), Niobium Titanium Oxynitride (NbTiON), Niobium Tantalum Oxide (NbTaO), Niobium Tantalum Nitride (NbTaN), Niobium Tantalum Oxynitride (NbTaON), Molybdenum Titanium Oxide (MoTiO), Molybdenum Titanium Nitride (MoTiN), Molybdenum Titanium Oxynitride (MoTiON), Molybdenum Tantalum Oxide (MoTaO), Molybdenum Tantalum Nitride (MoTaN), Molybdenum Tantalum Oxynitride (MoTaON), Indium Titanium Oxide (InTiO), Indium Titanium Nitride (InTiN), Indium Titanium Oxynitride (InTiON), Indium Tantalum Oxide (InTaO), Indium Tantalum Nitride (InTaN), Indium Tantalum Oxynitride (InTaON), or any combination thereof.

The supports 73 and 74 may be disposed on the side surfaces of the auxiliary layer 63. The supports 73 and 74 may serve to support the lower electrode 41 and the auxiliary layer 63. The etch stop layer 35, the intermediate support 73, and the upper support 74 may be spaced apart from each other in a vertical direction to the top surface (or upper surface) of the substrate 21. The intermediate support 73 may be disposed between the etch stop layer 35 and the upper support 74. The capacitor dielectric layer 76 may be disposed on the etch stop layer 35, the lower electrode 41, the auxiliary layer 63, and the supports 73 and 74. The upper electrode 89 may be disposed on the capacitor dielectric layer 76. The capacitor dielectric layer 76 may be interposed between the etch stop layer 35 and the upper electrode 89, between the auxiliary layer 63 and the upper electrode 89, and between the supports 73 and 74 and the upper electrode 89. In an embodiment, the etch stop layer 35 may be disposed between the capacitor dielectric layer 76 and the interlayer insulation layer 25, and between the capacitor dielectric layer 76 and the conductive pattern 31.

The lower electrode 41 may have a pillar shape extending in a vertical direction and may be surrounded by the auxiliary layer 63 at its lower surface (i.e., bottom surface) and side surface. The upper surface (i.e., the top surface) of the lower electrode 41 may be covered by the capacitor dielectric layer 76. The lower level auxiliary layer 63L may pass through the etch stop layer 35 to directly contact the upper surface of the conductive pattern 31. The lower level auxiliary layer 63L may be interposed between the conductive pattern 31 and the lower electrode 41. The lower level auxiliary layer 63L may extend between the etch stop layer 35 and the lower electrode 41. The lower level auxiliary layer 63L may directly contact the lower surface and the side surface of the lower electrode 41.

The intermediate level auxiliary layer 63M may be disposed between the side surface of the lower electrode 41 and the capacitor dielectric layer 76. The intermediate level auxiliary layer 63M may be disposed between the lower electrode 41 and the capacitor dielectric layer 76 between the etch stop layer 35 and the intermediate support 73. The intermediate level auxiliary layer 63M may be disposed between the lower electrode 41 and the capacitor dielectric layer 76 between the intermediate support 73 and the upper support 74. The upper level auxiliary layer 63U may be disposed between the lower electrode 41 and the intermediate support 73 and between the lower electrode 41 and the upper support 74.

The thickness of the intermediate level auxiliary layer 63M refers to the horizontal width of the intermediate level auxiliary layer 63M. The intermediate level auxiliary layer 63M has a first thickness T1. The intermediate level auxiliary layer 63M may directly contact the side surface of the lower electrode 41 and the side surface of the capacitor dielectric layer 76. The thickness of the intermediate level auxiliary layer 63M may correspond to the minimum distance between the side surface of the lower electrode 41 and the side surface of the capacitor dielectric layer 76.

The thickness of the upper level auxiliary layer 63U may correspond to the horizontal width of the upper level auxiliary layer 63U. The upper level auxiliary layer 63U has a second thickness T2. The upper level auxiliary layer 63U may directly contact the side surface of the lower electrode 41 and the side surfaces of the supports 73 and 74. The thickness of the upper level auxiliary layer 63U may correspond to the minimum distance between the side surface of the lower electrode 41 and the side surface of the upper support 74. The thickness of the upper level auxiliary layer 63U may correspond to the minimum distance between the side surface of the lower electrode 41 and the side surface of the intermediate support 73.

In an embodiment, the intermediate level auxiliary layer 63M may have a thickness thinner than that of the upper level auxiliary layer 63U. The first thickness T1 may be thinner than the second thickness T2. A distance between the side surface of the lower electrode 41 and the side surface of the capacitor dielectric layer 76 may be smaller than a distance between the side surface of the lower electrode 41 and the side surface of the intermediate support 73. A distance between the side surface of the lower electrode 41 and the side surface of the capacitor dielectric layer 76 may be smaller than a distance between the side surface of the lower electrode 41 and the side surface of the upper support 74.

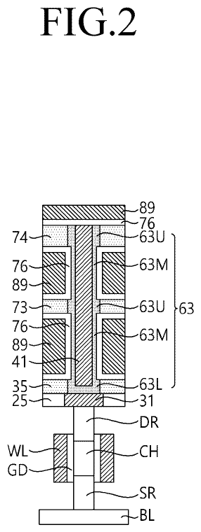

Referring to FIG. 2, a semiconductor device according to embodiments of the present disclosure may include a bit line BL, a word line WL, a source area SR, a channel area CH, a drain area DR, a gate dielectric layer GD, an interlayer insulation layer 25, a conductive pattern 31, an etch stop layer 35, a lower electrode 41, an auxiliary layer 63, supports 73 and 74, a capacitor dielectric layer 76, and an upper electrode 89. Only the differences from the embodiment of FIG. 1 are described below.

The source area SR may be connected to the bit line BL. The bit line BL may extend in a horizontal direction and the source area SR extends over the bit line BL in a vertical direction. The drain area DR may be disposed to face the source area SR. The channel area CH may be disposed between the source area SR and the drain area DR. The channel area CH may contact the source area SR and the drain area DR. The source area SR, the channel area CH and the drain area DR may be aligned in the vertical direction over the bit line BL forming a pillar shape structure. The word line WL may be disposed adjacent to the channel area CH in a horizontal direction. The gate dielectric layer GD may be disposed between the word line WL and the channel area CH. The conductive pattern 31 may be connected to the drain area DR. It is noted that the reference to the terms “horizontal direction” and “vertical direction” are used herein for ease of understanding the relative positioning of the elements within the described structure. However, these directions are interchangeable, and the described arrangement would remain conceptually the same if the horizontal elements were oriented vertically and vice versa.

The word line WL may serve as a gate electrode. The word line WL, the source area SR, the channel area CH, the drain area DR, and the gate dielectric layer GD may constitute a transistor. In an embodiment, the transistor may include a planar transistor, a fin field effect transistor (FinFET), a gate all around FET (GAAFET), a multi-bridge channel FET (MBCFET), a recess channel transistor, a vertical channel transistor, or a combination thereof.

The bit line BL and the word line WL may include a single layer or multiple layers. Each of the bit line BL and the word line WL may include a conductive material such as a metal, metal oxide, metal nitride, metal silicide, polysilicon, conductive carbon, or a combination thereof. The gate dielectric layer GD may include a single layer or multiple layers. The gate dielectric layer GD may include Silicon Oxide (SiO₂), Silicon Nitride (Si₃N₄), Silicon Oxynitride (SiON), a high-K dielectric, or any combination thereof. The source area SR, the channel area CH, and the drain area DR may include a single layer or multiple layers. The source area SR, the channel area CH, and the drain area DR may include mono-crystalline silicon, polysilicon, amorphous silicon, mono-crystalline silicon germanium, poly-crystalline silicon germanium, carbon-doped silicon, or a combination thereof. The source area SR, the channel area CH, and the drain area DR may include a group III-V semiconductor pattern, e.g., a compound semiconductor pattern such as gallium arsenide (GaAs). In an embodiment, the channel area CH may include a silicon layer having P-type impurities. The P-type impurities may include Boron (B), Boron Fluoride (BF), or a combination thereof. The source area (SR) and the drain area (DR) may include a silicon layer having N-type impurities, a silicon germanium layer (SiGe) having N-type impurities, or a combination thereof. The N-type impurities may include Phosphorus (P), Arsenic (As), or a combination thereof.

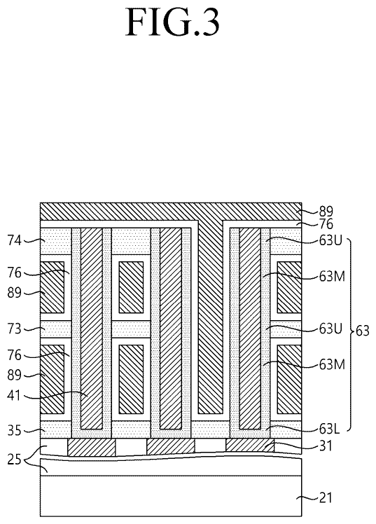

Referring to FIG. 3, the lower level auxiliary layer 63L, the intermediate level auxiliary layer 63M, and the upper level auxiliary layer 63U may have the same or substantially the same thickness. The intermediate level auxiliary layer 63M may have the same or substantially the same thickness as the upper level auxiliary layer 63U. The distance between the side surface of the lower electrode 41 and the side surface of the capacitor dielectric layer 76 may be the same or substantially the same as the distance between the side surface of the lower electrode 41 and the side surface of the intermediate support 73. The distance between the side surface of the lower electrode 41 and the side surface of the capacitor dielectric layer 76 may be the same or substantially the same as the distance between the side surface of the lower electrode 41 and the side surface of the upper support 74.

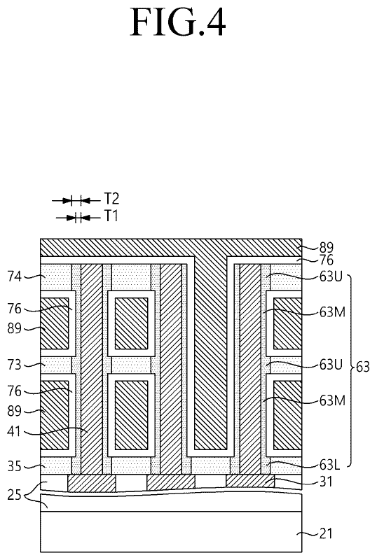

Referring to FIG. 4, the lower electrode 41 may pass through the auxiliary layer 63 in the vertical direction to directly contact the conductive pattern 31. The lower level auxiliary layer 63L may pass through the etch stop layer 35 in the vertical direction to contact the conductive pattern 31. The lower level auxiliary layer 63L may be disposed between the etch stop layer 35 and the lower electrode 41. The lower level auxiliary layer 63L may contact the side surface of the etch stop layer 35 and the side surface of the lower electrode 41. In an embodiment, the intermediate level auxiliary layer 63M may have a thickness thinner than that of the upper level auxiliary layer 63U.

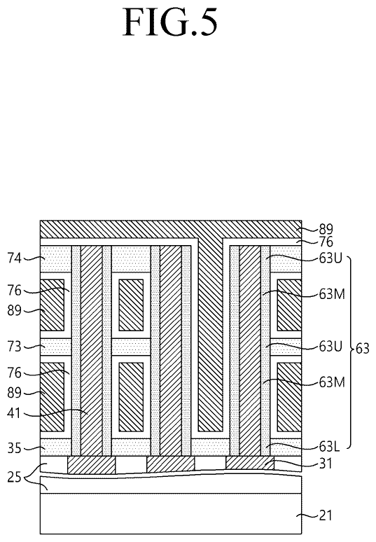

Referring to FIG. 5, the lower electrode 41 may pass through the auxiliary layer 63 to directly contact the conductive pattern 31. The lower level auxiliary layer 63L may be disposed between the etch stop layer 35 and the lower electrode 41. The lower level auxiliary layer 63L, the intermediate level auxiliary layer 63M, and the upper level auxiliary layer 63U may have the same or substantially the same thickness.

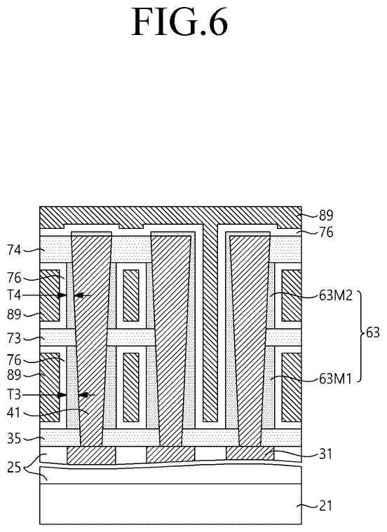

Referring to FIG. 6, the lower electrode 41 may pass through the etch stop layer 35 to directly contact the conductive pattern 31. The side surface of the lower electrode 41 may contact the etch stop layer 35. The lower electrode 41 may include an inverted trapezoid shape in which the width of the lower portion is narrower than the width of the upper portion. Stated differently, the lower electrode may have a tapered shape in which the width of the lower portion is narrower than the width of the upper portion. The lower electrode 41 may have an inclined side surface. The intermediate support 73 and the upper support 74 may directly contact the side surface of the lower electrodes 41.

The auxiliary layer 63 may include a first intermediate level auxiliary layer 63M1 and a second intermediate level auxiliary layer 63M2. The first intermediate level auxiliary layer 63M1 may be disposed between the lower electrode 41 and the capacitor dielectric layer 76 between the etch stop layer 35 and the intermediate support 73. The first intermediate level auxiliary layer 63M1 may directly contact the side surface of the lower electrode 41 and the side surface of the capacitor dielectric layer 76. The lower surface of the first intermediate level auxiliary layer 63M1 may contact the upper surface of the etch stop layer 35. The upper surface of the first intermediate level auxiliary layer 63M1 may contact the lower surface of the intermediate support 73.

The second intermediate level auxiliary layer 63M2 may be disposed between the lower electrode 41 and the capacitor dielectric layer 76 between the intermediate support 73 and the upper support 74. The second intermediate level auxiliary layer 63M2 may directly contact the side surface of the lower electrode 41 and the side surface of the capacitor dielectric layer 76. The second intermediate level auxiliary layer 63M2 may be disposed between the upper support 74 and the intermediate support 73. The lower surface of the second intermediate level auxiliary layer 63M2 may contact the upper surface of the intermediate support 73. The upper surface of the second intermediate level auxiliary layer 63M2 may contact the lower surface of the upper support 74.

The lower electrode 41 may include a lower area close to the conductive pattern 31 and an upper area far from the conductive pattern 31. The auxiliary layer 63 may include a lower area close to the conductive pattern 31 and an upper area far from the conductive pattern 31. The lower area of the auxiliary layer 63 may have a larger thickness than the upper area of the auxiliary layer 63. The thickness of the auxiliary layer 63 may gradually increase from the upper area to the lower area.

In an embodiment, the first intermediate level auxiliary layer 63M1 disposed on the side surface of the lower area of the lower electrode 41 has a third thickness T3. The second intermediate level auxiliary layer 63M2 disposed on the side surface of the upper area of the lower electrode 41 has a fourth thickness T4. The third thickness T3 may be thicker than the fourth thickness T4.

The lower area of the lower electrode 41 may have a horizontal width thinner than that of the upper area of the lower electrode 41. The auxiliary layer 63 may surround the side surface of the lower electrode 41. The auxiliary layer 63 may serve to compensate for a horizontal width difference between the upper area and the lower area of the lower electrode 41. The horizontal widths obtained by combining the auxiliary layer 63 and the lower electrode 41 may be the same or substantially the same in the upper area and the lower area. The auxiliary layer 63 may include an inner surface and an outer surface facing each other. The inner surface of the auxiliary layer 63 may contact the lower electrode 41. The outer surface of the auxiliary layer 63 may be spaced apart from the lower electrode 41. The outer surface of the auxiliary layer 63 may contact the capacitor dielectric layer 76. The outer surface of the auxiliary layer 63 may have a profile substantially perpendicular to the upper surface of the conductive pattern 31.

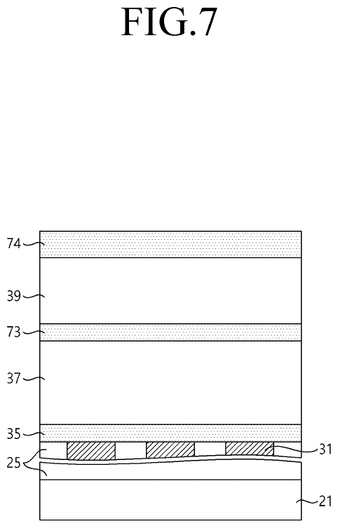

FIGS. 7 to 14 are cross-sectional views illustrating a method for forming a semiconductor device according to embodiments of the present disclosure.

Referring to FIG. 7, a conductive pattern 31 may be formed in an interlayer insulation layer 25 on a substrate 21. An etch stop layer 35 covering the interlayer insulation layer 25 and the conductive pattern 31 may be formed. Mold layers 37 and 39 and supports 73 and 74 may be formed on the etch stop layer 35 with the support 73 disposed between the mold layers 37 and 39 and the support 74 disposed on the support 74.

The substrate 21 may include a semiconductor substrate such as a silicon wafer or a silicon on insulator (SOI) wafer. The substrate 21 may include a group III-V semiconductor substrate, e.g., a compound semiconductor substrate such as GaAs. The substrate 21 may include monocrystalline silicon, polysilicon, amorphous silicon, monocrystalline silicon germanium, polycrystalline silicon germanium, carbon-doped silicon, or a combination thereof.

The interlayer insulation layer 25 may cover the substrate 21. The interlayer insulation layer 25 may include a single layer or multiple layers. The interlayer insulation layer 25 may include at least two selected from the group consisting of Si, O, N, C, B, P, and H. The interlayer insulation layer 25 may include silicon oxide, silicon nitride, silicon oxynitride, a low-K dielectric material, a high-K dielectric material, or a combination thereof.

Although not shown, active/passive devices such as an element isolation layer, a word line, a bit line, a contact plug, and a transistor may be formed inside the substrate 21, between the substrate 21 and the interlayer insulation layer 25, and inside the interlayer insulation layer 25, but are omitted from the description for brevity. The conductive pattern 31 may be electrically connected to active/passive elements (not shown) in the substrate 21 and/or the interlayer insulation layer 25.

In an embodiment, the conductive pattern 31 may correspond to a landing pad, a buried contact plug, or a storage node contact plug. A plurality of conductive patterns 31 may be formed at regular intervals. The conductive pattern 31 may include a single layer or multiple layers. The conductive pattern 31 may include a metal, metal oxide, metal nitride, metal silicide, polysilicon, conductive carbon, or a combination thereof.

The mold layers 37 and 39 and the supports 73 and 74 may be alternately stacked on the etch stop layer 35. In an embodiment, the first mold layer 37, the intermediate support 73, the second mold layer 39, and the upper support 74 may be sequentially stacked on the etch stop layer 35. The etch stop layer 35 may include a material having etching selectivity with respect to the first mold layer 37 and the interlayer insulation layer 25. The intermediate support 73 may include a material having etch selectivity with respect to the first mold layer 37 and the second mold layer 39. The upper support 74 may include a material having etch selectivity with respect to the second mold layer 39. Each of the etch stop layer 35, the first mold layer 37, the intermediate support 73, the second mold layer 39, and the upper support 74 may include a single layer or multiple layers. Each of the etch stop layer 35, the intermediate support 73, and the upper support 74 may include SiN, SiON, SiCN, SiOCN, or a combination thereof. Each of the first mold layer 37 and the second mold layer 39 may include silicon oxide, phosphorus (P)-doped silicon oxide, boron (B)-doped silicon oxide, or a combination thereof.

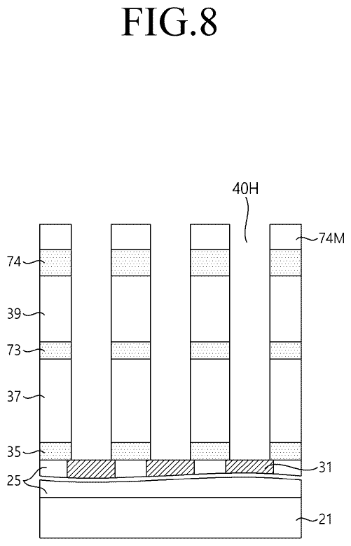

Referring to FIG. 8, a first mask pattern 74M may be formed on the upper support 74. An electrode hole 40H passing through the upper support 74, the second mold layer 39, the intermediate support 73, the first mold layer 37, and the etch stop layer 35 may be formed using the first mask pattern 74M as an etching mask. The conductive pattern 31 may be exposed to the bottom of the electrode hole 40H. The upper support 74, the second mold layer 39, the intermediate support 73, the first mold layer 37, and the etch stop layer 35 may be exposed on sidewalls of the electrode hole 40H.

The first mask pattern 74M may include a photoresist layer, a hard mask layer, or a combination thereof. Forming the electrode hole 40H may include an anisotropic etching process. The height of the electrode hole 40H may be larger than the horizontal width. The electrode hole 40H may be aligned on the conductive pattern 31. The electrode hole 40H may overlap the conductive pattern 31. A plurality of electrode holes 40H may be formed at regular intervals.

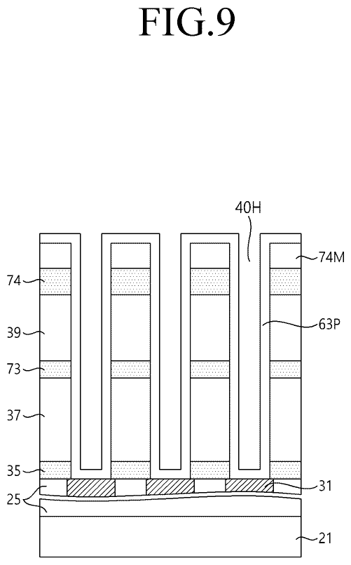

Referring to FIG. 9, a preliminary auxiliary layer 63P may be formed in the electrode hole 40H. The preliminary auxiliary layer 63P may cover the sidewall and the bottom of the electrode hole 40H in a uniform thickness. The preliminary auxiliary layer 63P may directly contact the conductive pattern 31 and the supports 73 and 74. The preliminary auxiliary layer 63P may include a single layer or multiple layers. The preliminary auxiliary layer 63P may include Niobium (Nb), Molybdenum (Mo), Indium (In), Niobium Oxide (NbO), Molybdenum Oxide (MoO), Indium Oxide (InO), Niobium Nitride (NbN), Molybdenum Nitride (MoN), Indium Nitride (InN), Niobium Oxynitride (NbON), Molybdenum Oxynitride (MoON), Indium Oxynitride (InON), or any combination thereof. The preliminary auxiliary layer 63P may be formed to have a thickness of 0.1 nm to 2 nm. In an embodiment, the preliminary auxiliary layer 63P may include a NbO layer having a thickness of about 2 nm.

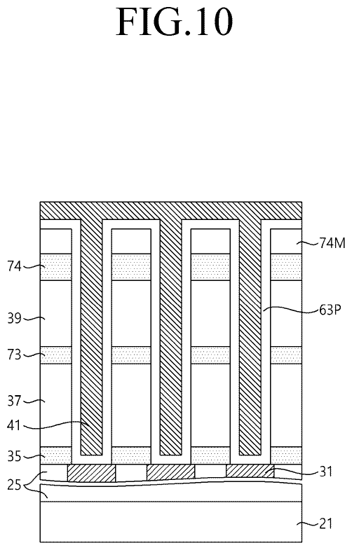

Referring to FIG. 10, a lower electrode 41 may be formed on the preliminary auxiliary layer 63P. In an embodiment, the lower electrode 41 may be formed to completely fill the electrode hole 40H. The lower electrode 41 may directly contact the preliminary auxiliary layer 63P. The lower electrode 41 may include a single layer or multiple layers. The lower electrode 41 may include Ti, Ta, TiN, TaN, TiO, TaO, TiON, TaON, or a combination thereof.

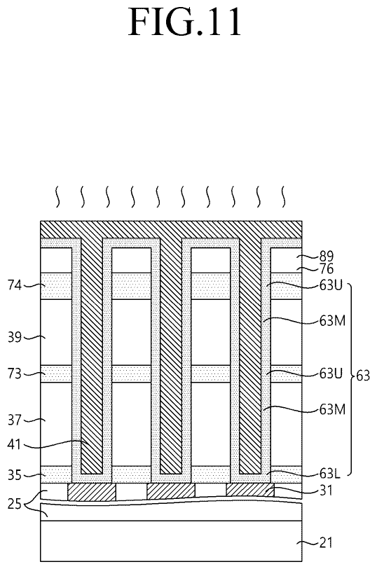

Referring to FIG. 11, the auxiliary layer 63 may be formed using a heat treatment process. The auxiliary layer 63 may include a single layer or multiple layers. The auxiliary layer 63 may include NbTiO, NbTiN, NbTiON, NbTaO, NbTaN, NbTaON, MoTiO, MoTiN, MoTiON, MoTaO, MoTaN, MoTaON, InTiO, InTiN, InTiON, InTaO, InTaN, InTaON, or a combination thereof. The auxiliary layer 63 may include a lower level auxiliary layer 63L, an intermediate level auxiliary layer 63M, and an upper level auxiliary layer 63U.

In an embodiment, the auxiliary layer 63 may be formed by diffusing the metal in the lower electrode 41 into the preliminary auxiliary layer 63P using a heat treatment process. The heat treatment process for forming the auxiliary layer 63 may be performed, for example, in a temperature range of 300° C. to 700° C. for 10 minutes to 80 minutes. The heat treatment process for forming the auxiliary layer 63 may be performed in an atmosphere in which an inert gas, a reducing gas, or a combination thereof is supplied. The inert gas may include He, AR, N₂, or a combination thereof. The reducing gas may include NH₃, H₂, or a combination thereof. The heat treatment process for forming the auxiliary layer 63 may be performed using a batch type heat treatment device, a rapid thermal annealing (RTA) device, a laser heat treatment device, a microwave heat treatment device, or a combination thereof.

The lower level auxiliary layer 63L may be formed between the lower electrode 41 and the conductive pattern 31, and between the lower electrode 41 and the etch stop layer 35. The lower level auxiliary layer 63L may surround the side surface and the bottom of the lower electrode 41. The lower level auxiliary layer 63L may directly contact the conductive pattern 31, the etch stop layer 35, and the lower electrode 41.

The intermediate level auxiliary layer 63M may be formed between the lower electrode 41 and the first mold layer 37, and between the lower electrode 41 and the second mold layer 39. The intermediate level auxiliary layer 63M may surround the side surface of the lower electrode 41. The intermediate level auxiliary layer 63M may directly contact the first mold layer 37, the second mold layer 39, and the lower electrode 41.

The upper level auxiliary layer 63U may be formed between the lower electrode 41 and the intermediate support 73 and between the lower electrode 41 and the upper support 74. The upper level auxiliary layer 63U may surround the side surface of the lower electrode 41. The upper level auxiliary layer 63U may directly contact the intermediate support 73, the upper support 74, and the lower electrode 41.

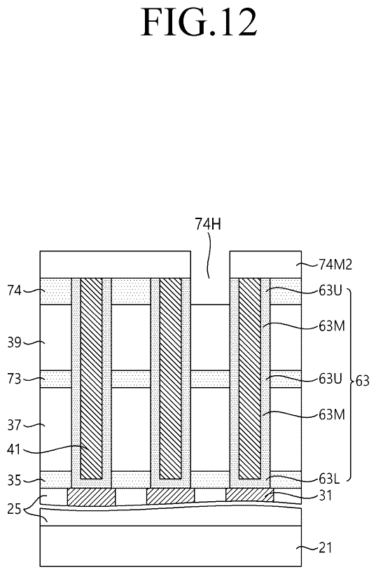

Referring to FIG. 12, the first mask pattern 74M may be removed and a second mask pattern 74M2 may be formed on the upper support 74. While the first mask pattern 74M is removed, the lower electrode 41 and the auxiliary layer 63 may be partially removed. The lower electrode 41 and the auxiliary layer 63 may remain in the electrode hole 40H of FIG. 8.

The second mask pattern 74M2 formed on the upper support 74 may include a photoresist layer, a hard mask layer, or a combination thereof. An upper through hole 74H passing through the upper support 74 may be formed using the second mask pattern 74M2 as an etching mask. The second mold layer 39 may be exposed to the bottom of the upper through hole 74H.

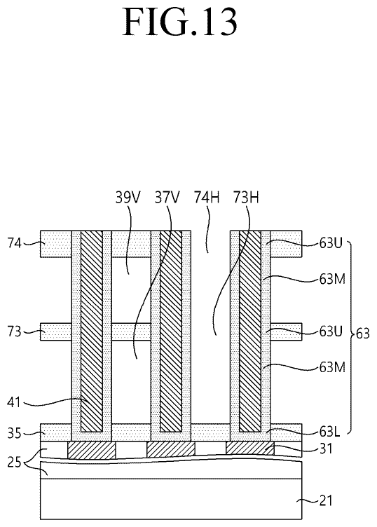

Referring to FIG. 13, an upper space 39V may be formed by removing the second mold layer 39. The intermediate support 73 may be exposed to the bottom of the upper space 39V. The side surface of the intermediate level auxiliary layer 63M may be exposed in the upper space 39V. The upper support 74 may be exposed to the ceiling of the upper space 39V. The upper space 39V may communicate with the bottom of the upper through hole 74H.

An intermediate through hole 73H penetrating the intermediate support 73 may be formed using the second mask pattern 74M2 as an etching mask. The intermediate through hole 73H may be aligned with a lower portion of the upper through hole 74H. The intermediate through hole 73H may communicate with the bottom of the upper space 39V.

The first mold layer 37 may be exposed to the bottom of the intermediate through hole 73H. The lower space 37V may be formed by removing the first mold layer 37. The lower space 37V may communicate with the bottom of the intermediate through hole 73H. The etch stop layer 35 may be exposed to the bottom of the lower space 37V. The side surface of the intermediate level auxiliary layer 63M may be exposed in the lower space 37V. The intermediate support 73 may be exposed to the ceiling of the lower space 37V. The second mask pattern 74M2 may be removed.

Removing the second mold layer 39 and the first mold layer 37 may include an isotropic etching process. The auxiliary layer 63 may have etch selectivity with respect to the first mold layer 37 and the second mold layer 39. While the process of removing the second mold layer 39 and the first mold layer 37 is performed, the auxiliary layer 63 may serve to prevent etching damage to the lower electrode 41.

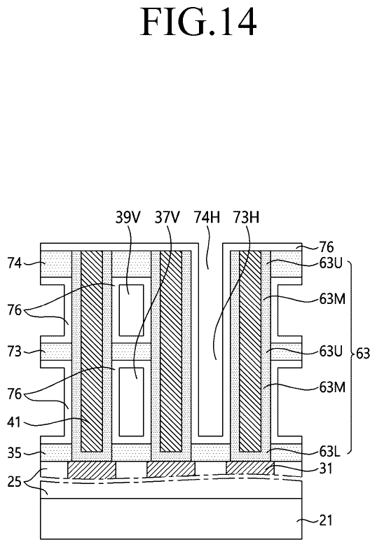

Referring to FIG. 14, a capacitor dielectric layer 76 may be formed on the etch stop layer 35, the lower electrode 41, the auxiliary layer 63, and the supports 73 and 74. The capacitor dielectric layer 76 may conformally cover inner walls of the lower space 37V, the intermediate through hole 73H, the upper space 39V, and the upper through hole 74H. The capacitor dielectric layer 76 may be formed to cover the etch stop layer 35, the lower electrode 41, the intermediate support 73, and the upper support 74 in a uniform thickness. The capacitor dielectric layer 76 may cover the uppermost surfaces of the lower electrode 41 and the upper support 74. The auxiliary layer 63 may be interposed between the lower electrode 41 and the capacitor dielectric layer 76. The auxiliary layer 63 may serve the function of preventing oxidation of the lower electrode 41 while forming the capacitor dielectric layer 76.

The capacitor dielectric layer 76 may include a single layer or multiple layers. The capacitor dielectric layer 76 may include silicon oxide, silicon nitride, silicon oxynitride, hafnium oxide (HfO₂), zirconium oxide (ZrO₂), aluminum oxide (Al₂O₃), titanium oxide (TiO₂), tantalum oxide (Ta₂O₅), niobium oxide (Nb₂O₅), strontium titanium oxide (SrTiO₃), ZAZ(ZrO2/Al2O3/ZrO2) stack, TiO2/ZrO2/Al2O3/ZrO2 stack, TiO2/HfO2/Al2O3/HfO2 stack, Ta2O5/ZrO2/Al2O3/ZrO2 stack, Ta2O5/HfO2/Al2O3/HfO2 stack, or a combination thereof.

Referring back to FIGS. 14 and 3, an upper electrode 89 may be formed on the capacitor dielectric layer 76. The upper electrode 89 may be formed to completely fill the inside of the lower space 37V, the intermediate through hole 73H, the upper space 39V, and the upper through hole 74H. The upper electrode 89 may cover the uppermost surface of the capacitor dielectric layer 76. The upper electrode 89 may include a single layer or multiple layers. The upper electrode 89 may include a metal, metal oxide, metal nitride, metal silicide, polysilicon, conductive carbon, or a combination thereof.

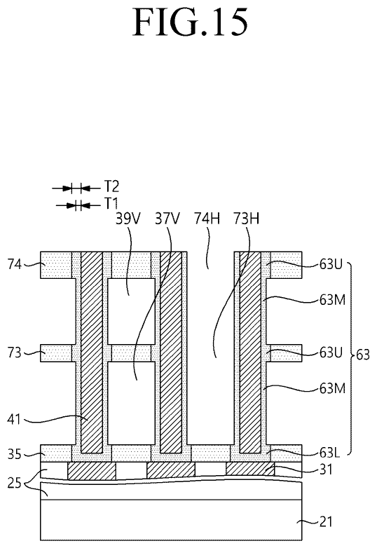

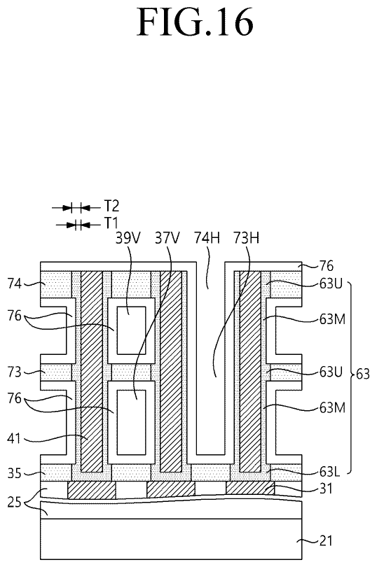

FIGS. 15 and 16 are cross-sectional views illustrating a method for forming a semiconductor device according to embodiments of the present disclosure.

Referring to FIG. 15, the removal of the second mold layer 39 and the first mold layer 37 may include an isotropic etching process. While the etching process of removing the second mold layer 39 and the first mold layer 37 is performed, the intermediate level auxiliary layer 63M may be etched to reduce its thickness. The intermediate level auxiliary layer 63M may have a first thickness T1. The upper level auxiliary layer 63U may have a second thickness T2. The first thickness T1 may be thinner than the second thickness T2. The lower level auxiliary layer 63L may have the same or substantially the same thickness as the upper level auxiliary layer 63U.

Referring to FIG. 16, a capacitor dielectric layer 76 may be formed on the etch stop layer 35, the lower electrode 41, the auxiliary layer 63, and the supports 73 and 74. The capacitor dielectric layer 76 may conformally cover inner walls of the lower space 37V, the intermediate through hole 73H, the upper space 39V, and the upper through hole 74H. The auxiliary layer 63 may be interposed between the lower electrode 41 and the capacitor dielectric layer 76.

Referring back to FIGS. 16 and 1, an upper electrode 89 may be formed on the capacitor dielectric layer 76. The upper electrode 89 may be formed to completely fill the inside of the lower space 37V, the intermediate through hole 73H, the upper space 39V, and the upper through hole 74H. The upper electrode 89 may cover the uppermost surface of the capacitor dielectric layer 76.

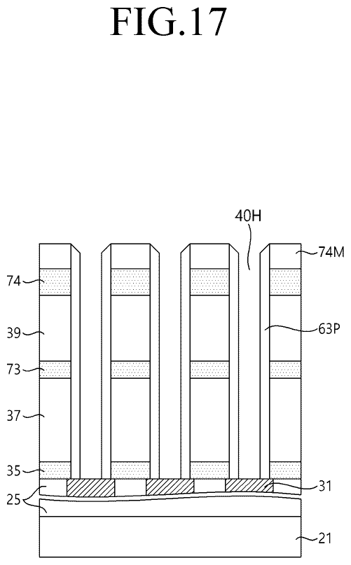

FIGS. 17 to 21 are cross-sectional views illustrating a method for forming a semiconductor device according to embodiments of the present disclosure.

Referring to FIG. 17, forming the preliminary auxiliary layer 63P may include a thin film forming process and an anisotropic etching process. The preliminary auxiliary layer 63P may remain on the sidewall of the electrode hole 40H. The conductive pattern 31 may be exposed to the bottom of the electrode hole 40H.

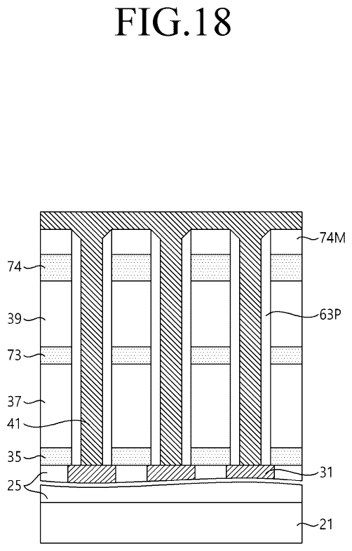

Referring to FIG. 18, a lower electrode 41 filling the electrode hole 40H may be formed on the preliminary auxiliary layer 63P. In an embodiment, the lower end of the lower electrode 41 may directly contact the conductive pattern 31.

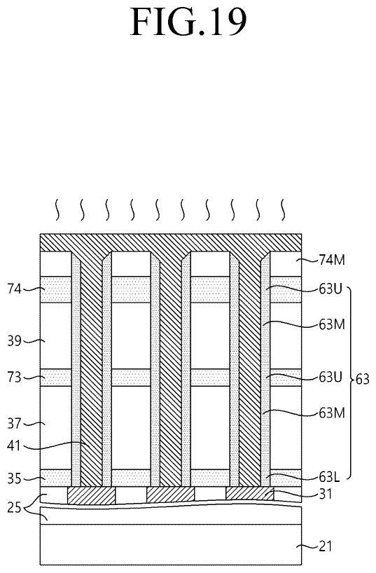

Referring to FIG. 19, the auxiliary layer 63 may be formed using a heat treatment process. The lower level auxiliary layer 63L may be formed between the lower electrode 41 and the etch stop layer 35. The lower level auxiliary layer 63L may surround the side surface of the lower electrode 41. The lower level auxiliary layer 63L may directly contact the conductive pattern 31, the etch stop layer 35, and the lower electrode 41.

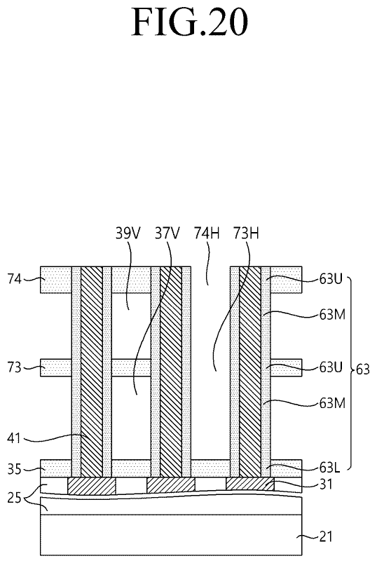

Referring to FIG. 20, the first mask pattern 74M may be removed. While the first mask pattern 74M is removed, the lower electrode 41 and the auxiliary layer 63 may be partially removed. An upper through hole 74H passing through the upper support 74 may be formed. An upper space 39V may be formed by removing the second mold layer 39. An intermediate through hole 73H penetrating the intermediate support 73 may be formed. The lower space 37V may be formed by removing the first mold layer 37.

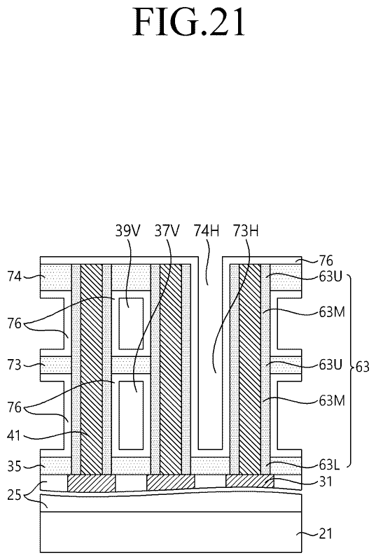

Referring to FIG. 21, a capacitor dielectric layer 76 may be formed on the etch stop layer 35, the lower electrode 41, the auxiliary layer 63, and the supports 73 and 74.

Referring back to FIGS. 21 and 5, an upper electrode 89 may be formed on the capacitor dielectric layer 76. The upper electrode 89 may be formed to completely fill the inside of the lower space 37V, the intermediate through hole 73H, the upper space 39V, and the upper through hole 74H. The upper electrode 89 may cover the uppermost surface of the capacitor dielectric layer 76.

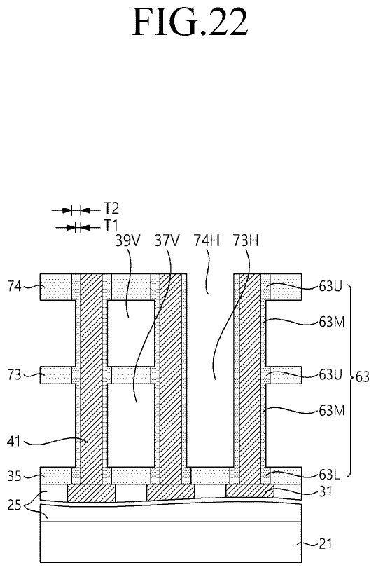

FIG. 22 is a cross-sectional view illustrating a method for forming a semiconductor device according to embodiments of the present disclosure.

Referring to FIG. 22, while the etching process of removing the second mold layer 39 and the first mold layer 37 is performed, the intermediate level auxiliary layer 63M may be etched to reduce its thickness. The intermediate level auxiliary layer 63M may have first thickness T1. The upper level auxiliary layer 63U may have a second thickness T2. The first thickness T1 may be thinner than the second thickness T2. The lower level auxiliary layer 63L may have the same or substantially the same thickness as the upper level protective layer 63U.

Referring back to FIGS. 22 and 4, a capacitor dielectric layer 76 may be formed on the etch stop layer 35, the lower electrode 41, the auxiliary layer 63, and the supports 73 and 74. An upper electrode 89 may be formed on the capacitor dielectric layer 76.

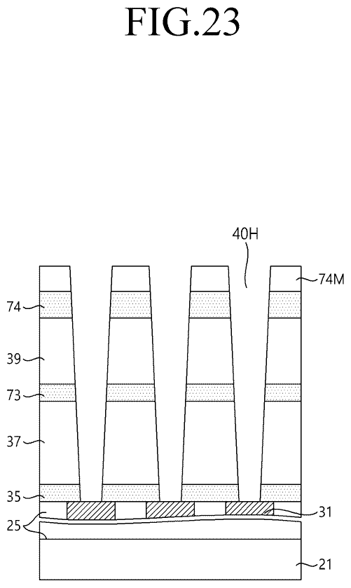

FIGS. 23 to 28 are cross-sectional views illustrating a method for forming a semiconductor device according to embodiments of the present disclosure.

Referring to FIG. 23, an electrode hole 40H passing through the upper support 74, the second mold layer 39, the intermediate support 73, the first mold layer 37, and the etch stop layer 35 may be formed using the first mask pattern 74M as an etching mask. The electrode hole 40H may expose the upper surface of the conductive pattern 31. The electrode hole 40H may be tapered with the width of the lower portion being narrower than the width of the upper portion. The shape of the electrode hole 40H may include an inverted trapezoid shape (or tapered shape) in which the width of the lower portion is narrower than the width of the upper portion. The electrode hole 40H may have an inclined sidewall.

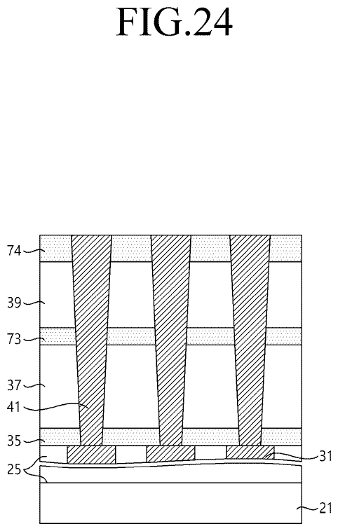

Referring to FIG. 24, a lower electrode 41 may be formed in the electrode hole 40H. The first mask pattern 74M may be removed. The shape of the lower electrode 41 may be determined by the electrode hole 40H. The lower electrode 41 may include the inverted trapezoid shape (or tapered shape) in which the width of the lower portion is narrower than the width of the upper portion. The lower electrode 41 may have an inclined side surface. The side surface of the lower electrode 41 may directly contact the etch stop layer 35, the intermediate support 73, and the upper support 74. The lower surface of the lower electrode 41 may directly contact the conductive pattern 31.

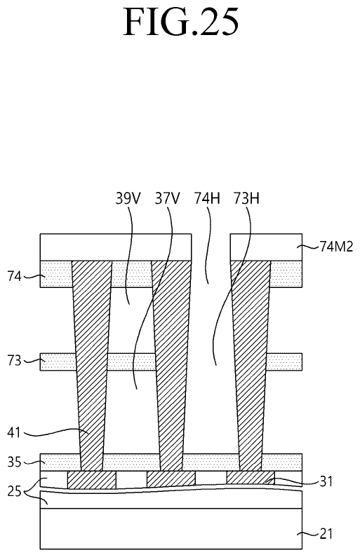

Referring to FIG. 25, a second mask pattern 74M2 may be formed on the upper support 74. An upper through hole 74H penetrating the upper support 74 may be formed using the second mask pattern 74M2 as an etching mask. An upper space 39V may be formed by removing the second mold layer 39. A side surface of the lower electrode 41 may be exposed in the upper space 39V. An intermediate through hole 73H penetrating the intermediate support 73 may be formed. The lower space 37V may be formed by removing the first mold layer 37. A side surface of the lower electrode 41 may be exposed in the lower space 37V.

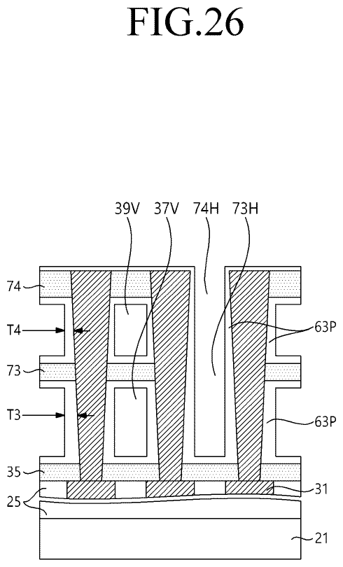

Referring to FIG. 26, the second mask pattern 74M2 may be removed. A preliminary auxiliary layer 63P may be formed on inner walls of the lower space 37V, the intermediate through hole 73H, the upper space 39V, and the upper through hole 74H. The preliminary auxiliary layer 63P may extend onto upper surfaces of the upper support 74 and the lower electrode 41.

In an embodiment, forming the preliminary auxiliary layer 63P may include an atomic layer deposition (ALD) process or a cyclic deposition process. Forming the preliminary auxiliary layer 63P may include an area selective deposition (ASD) process. The ASD process may include sequentially performing supply of pre-treatment gas including a surface inhibitor on the substrate 21 in the process chamber, supply of a first purge gas in the process chamber, supply of a first reaction gas on the substrate 21 in the process chamber, supply of a second purge gas in the process chamber, supply of a second reaction gas on the substrate 21 in the process chamber, and supply of a third purge gas in the process chamber.

In an embodiment, the surface inhibitor may include tetrahydrofuran (THF). The first reaction gas may include Nb, Mo, In, or a combination thereof. The second reaction gas may include N₂O, O₂, N₂, Ar, He, plasma thereof, or a combination thereof. Each of the first to third purge gases may include an inert gas such as argon, nitrogen, helium, neon, or a combination thereof. The preliminary auxiliary layer 63P may include Nb, Mo, In, NbO, MoO, InO, NbN, MoN, InN, NbON, MoON, InON, or a combination thereof.

While supplying the pre-treatment gas, the density of the surface inhibitor adsorbed on the surfaces of the etch stop layer 35, the intermediate support 73, and the upper support 74 may be higher than the density of the surface inhibitor adsorbed on the side surfaces of the lower electrode 41. The surface inhibitor may include a material that inhibits the formation of the preliminary auxiliary layer 63P. The thickness of the preliminary auxiliary layer 63P formed on the surfaces of the etch stop layer 35, the intermediate support 73, and the upper support 74 may be thinner than the thickness of the preliminary auxiliary layer 63P formed on the side surfaces of the lower electrode 41.

While supplying the pre-treatment gas, the density of the surface inhibitor adsorbed on the side surfaces of the lower electrode 41 may be adjusted according to the height of the lower electrode 41. The lower electrode 41 may include a lower area relatively close to the conductive pattern 31 and an upper area relatively far from the conductive pattern 31. In an embodiment, the density of the surface inhibitor adsorbed on the side surfaces of the upper area of the lower electrode 41 may be higher than the density of the surface inhibitor adsorbed on the side surfaces of the lower area of the lower electrode 41. The density of the surface inhibitor adsorbed on the side surfaces of the lower electrode 41 may be adjusted to gradually increase from the lower area to the upper area of the lower electrode 41.

The thickness of the preliminary auxiliary layer 63P formed on the side surfaces of the lower electrode 41 may be adjusted to become increasingly thicker from the upper area to the lower area of the lower electrode 41. The preliminary auxiliary layer 63P formed on the side surface of the lower area of the lower electrode 41 may have a third thickness T3. The preliminary auxiliary layer 63P formed on the side surface of the upper area of the lower electrode 41 may have a fourth thickness T4. The third thickness T3 may be thicker than the fourth thickness T4.

In an embodiment, the lower electrode 41 may include an inverted trapezoid shape (or tapered shape) in which the width of the lower portion is narrower than the width of the upper portion. The lower electrode 41 may have an inclined side surface. The thickness of the preliminary auxiliary layer 63P formed on the side surfaces of the lower electrode 41 may be adjusted to become thicker and thicker from the upper area to the lower area of the lower electrode 41. The preliminary auxiliary layer 63P may be formed to surround the side surface of the lower electrode 41. The horizontal widths obtained by combining the preliminary auxiliary layer 63P and the lower electrode 41 may be adjusted to be the same or substantially the same in the upper and lower areas. The outer surface of the preliminary auxiliary layer 63P may have a profile substantially perpendicular to the upper surface of the conductive pattern 31.

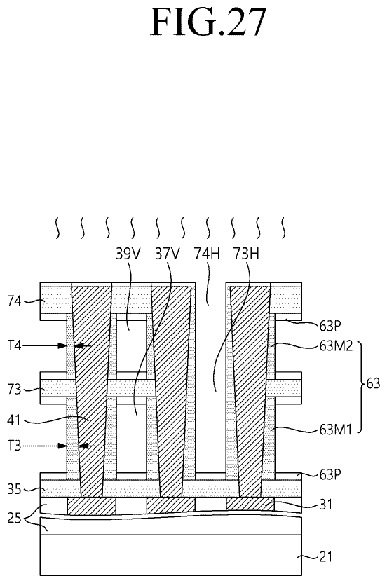

Referring to FIG. 27, the auxiliary layer 63 may be formed using a heat treatment process. The auxiliary layer 63 may include a single layer or multiple layers. The auxiliary layer 63 may include NbTiO, NbTiN, NbTiON, NbTaO, NbTaN, NbTaON, MoTiO, MoTiN, MoTiON, MoTaO, MoTaN, MoTaON, InTiO, InTiN, InTiON, InTaO, InTaN, InTaON, or a combination thereof. The auxiliary layer 63 may include a first intermediate level auxiliary layer 63M1 and a second intermediate level auxiliary layer 63M2.

In an embodiment, the auxiliary layer 63 may be formed by diffusing the metal in the lower electrode 41 into the preliminary auxiliary layer 63P using a heat treatment process. The heat treatment process for forming the auxiliary layer 63 may be performed, for example, in a temperature range of 300° C. to 700° C. for 10 minutes to 80 minutes. The heat treatment process for forming the auxiliary layer 63 may be performed in an atmosphere in which an inert gas, a reducing gas, or a combination thereof is supplied. The inert gas may include He, Ar, N₂, or a combination thereof. The reducing gas may include NH₃, H₂, or a combination thereof. The heat treatment process for forming the auxiliary layer 63 may be performed using a batch type heat treatment device, a rapid thermal annealing (RTA) device, a laser heat treatment device, a microwave heat treatment device, or a combination thereof.

The first intermediate level auxiliary layer 63M1 may be formed on the side surface of the lower electrode 41 between the etch stop layer 35 and the intermediate support 73. The lower surface of the first intermediate level auxiliary layer 63M1 may contact the etch stop layer 35. The upper surface of the first intermediate level auxiliary layer 63M1 may contact the lower surface of the intermediate support 73. The preliminary auxiliary layer 63P may partially remain on the upper surface of the etch stop layer 35 and the lower surface of the intermediate support 73 in the lower space 37V.

The second intermediate level auxiliary layer 63M2 may be formed on the side surface of the lower electrode 41 between the intermediate support 73 and the upper support 74. The lower surface of the second intermediate level auxiliary layer 63M2 may contact the upper surface of the intermediate support 73. The upper surface of the second intermediate level auxiliary layer 63M2 may contact the lower surface of the upper support 74. The preliminary auxiliary layer 63P may partially remain on the upper surface of the intermediate support 73 and the lower surface of the upper support 74 in the upper space 39V.

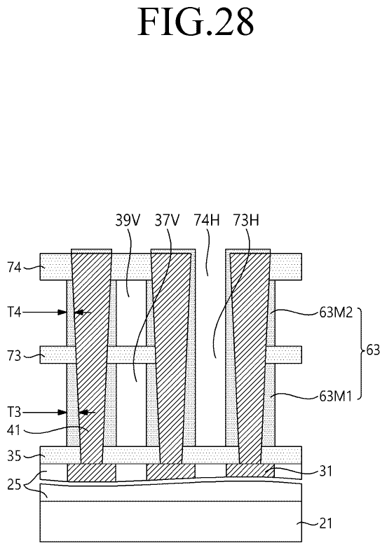

Referring to FIG. 28, the preliminary auxiliary layer 63P on the etch stop layer 35, the intermediate support 73, and the upper support 74 may be removed. The auxiliary layer 63 may have etch selectivity with respect to the preliminary auxiliary layer 63P. The etching rate of the preliminary auxiliary layer 63P may be faster than the etching rate of the auxiliary layer 63. The auxiliary layer 63 may remain on the side surface of the lower electrode 41.

Referring back to FIGS. 28 and 6, a capacitor dielectric layer 76 may be formed on the etch stop layer 35, the lower electrode 41, the auxiliary layer 63, and the supports 73 and 74. The capacitor dielectric layer 76 may conformally cover inner walls of the lower space 37V, the intermediate through hole 73H, the upper space 39V, and the upper through hole 74H. The capacitor dielectric layer 76 may be formed to cover the etch stop layer 35, the lower electrode 41, the intermediate support 73, and the upper support 74 in a uniform thickness. The capacitor dielectric layer 76 may cover the uppermost surfaces of the lower electrode 41 and the upper support 74. The auxiliary layer 63 may be interposed between the lower electrode 41 and the capacitor dielectric layer 76.

An upper electrode 89 may be formed on the capacitor dielectric layer 76. The upper electrode 89 may be formed to completely fill the inside of the lower space 37V, the intermediate through hole 73H, the upper space 39V, and the upper through hole 74H. The upper electrode 89 may cover the uppermost surface of the capacitor dielectric layer 76.

The auxiliary layer 63 may compensate for a horizontal width difference between the upper area and the lower area of the lower electrode 41. The outer surface of the auxiliary layer 63 may have a profile substantially perpendicular to the upper surface of the conductive pattern 31. The auxiliary layer 63 may prevent oxidation of the lower electrode 41 while forming the capacitor dielectric layer 76.

The technical concepts are disclosed together with the examples and embodiments described above. Those skilled in the relevant art will appreciate that various modifications, additions, and substitutions are possible without departing from the scope and technical concepts of the present disclosure. Therefore, the embodiments of the present disclosure should be considered from an illustrative, rather than a limiting, point of view. Therefore, the scope of the present disclosure is not limited to the above description. All changes within the meaning and equivalent scope of the claims are intended to be included within the scope of the claims. Furthermore, the embodiments may be combined to form additional embodiments.

What is claimed is:

1. A semiconductor device comprising:
a conductive pattern on a substrate;
a first electrode on the conductive pattern;
a support supporting the first electrode;
an auxiliary layer disposed on a side surface of the first electrode and extending between the first electrode and the support,
a capacitor dielectric layer on the auxiliary layer; and
a second electrode on the capacitor dielectric layer.

2. The semiconductor device of claim 1, wherein the auxiliary layer directly contacts a side surface of the first electrode.

3. The semiconductor device of claim 1, wherein the auxiliary layer includes:
an intermediate level auxiliary layer between the first electrode and the capacitor dielectric layer; and
an upper level auxiliary layer between the first electrode and the support.

4. The semiconductor device of claim 3, wherein the intermediate level auxiliary layer has a thinner thickness than the upper level auxiliary layer.

5. The semiconductor device of claim 3, wherein the intermediate level auxiliary layer has substantially the same thickness as the upper level auxiliary layer.

6. The semiconductor device of claim 3, further comprising an etch stop layer between the conductive pattern and the capacitor dielectric layer,
wherein the auxiliary layer further includes a lower level auxiliary layer penetrating the etch stop layer to contact the conductive pattern.

7. The semiconductor device of claim 6, wherein the lower level auxiliary layer is disposed between the conductive pattern and the first electrode.

8. The semiconductor device of claim 6, wherein the first electrode penetrates the lower level auxiliary layer to directly contact the conductive pattern.

9. The semiconductor device of claim 1, wherein the first electrode includes Ti, Ta, TiN, TaN, TiO, TaO, TiON, TaON, or a combination thereof, and wherein the auxiliary layer has NbTiO, NbTiN, NbTiON, NbTaO, NbTaN, NbTaON, MoTiO, MoTiN, MoTiON, MoTaO, MoTaN, MoTaON, InTiO, InTiN, InTiON, InTaO, InTaN, InTaON, or a combination thereof.

10. The semiconductor device of claim 9, wherein the capacitor dielectric layer extends between the support and the second electrode.

11. A semiconductor device comprising:
a conductive pattern on a substrate;
a first electrode on the conductive pattern;
a support supporting the first electrode;
an auxiliary layer on a side surface of the first electrode, and a lower area of the auxiliary layer close to the conductive pattern having a thicker thickness than an upper area relatively far from the conductive pattern;
a capacitor dielectric layer on the auxiliary layer; and
a second electrode on the capacitor dielectric layer.

12. The semiconductor device of claim 11, wherein the first electrode has an inclined side surface.

13. The semiconductor device of claim 11, wherein a lower area of the first electrode close to the conductive pattern has a narrower horizontal width than an upper area of the first electrode relatively far from the conductive pattern.

14. The semiconductor device of claim 11, wherein the first electrode includes Ti, Ta, TiN, TaN, TiO, TaO, TiON, TaON, or a combination thereof, and wherein the auxiliary layer has NbTiO, NbTiN, NbTiON, NbTaO, NbTaN, NbTaON, MoTiO, MoTiN, MoTiON, MoTaO, MoTaN, MoTaON, InTiO, InTiN, InTiON, InTaO, InTaN, InTaON, or a combination thereof.

15. The semiconductor device of claim 11, wherein an outer surface of the auxiliary layer has a profile substantially perpendicular to an upper surface of the conductive pattern.

16. The semiconductor device of claim 11, wherein the support directly contacts the side surface of the first electrode.

17. The semiconductor device of claim 11, further comprising an etch stop layer between the conductive pattern and the capacitor dielectric layer,
wherein the first electrode penetrates the etch stop layer to contact the conductive pattern.

18. The semiconductor device of claim 17, wherein a lower surface of the auxiliary layer contacts an upper surface of the etch stop layer.

19. A semiconductor device comprising:
a bit line;
a source area connected to the bit line;
a drain area facing the source area;
a channel area between the source area and the drain area;
a word line adjacent to the channel area;
a gate dielectric layer between the channel area and the word line;
a conductive pattern connected to the drain area;
a first electrode on the conductive pattern;
a support supporting the first electrode;
an auxiliary layer disposed on a side surface of the first electrode and extending between the first electrode and the support;
a capacitor dielectric layer on the auxiliary layer; and
a second electrode on the capacitor dielectric layer.

20. The semiconductor device of claim 19, wherein the auxiliary layer includes:
an intermediate level auxiliary layer between the first electrode and the capacitor dielectric layer; and
an upper level auxiliary layer between the first electrode and the support, and
wherein the intermediate level auxiliary layer has a thinner thickness than the upper level auxiliary layer,
wherein the auxiliary layer has NbTiO, NbTiN, NbTiON, NbTaO, NbTaN, NbTaON, MoTiO, MoTiN, MoTiON, MoTaO, MoTaN, MoTaON, InTiO, InTiN, InTiON, InTaO, InTaN, InTaON, or a combination thereof.
